(19) United States
(12) Patent Application Publication
(10) Pub. No.: US 2005/0139258 A1
(43) Pub. Date: Jun. 30, 2005

(54) Solar cell array control device

(76) Inventors: Yung-Hsiang Liu, Taipei City (TW); Guo-Shin Chu, Hsin Chu City (TW); Yung-Fu Huang, Ping Tung City (TW); Tain-Syh Luor, Chungho City (TW)

Correspondence Address: RABIN & BERDO, P.C., Suite 500, 1101 14 Street, N.W., Washington, DC, 20005, US

(21) Appl. No.: 10/745,620

(22) Filed: Dec. 29, 2003

(51) Int. Cl. H01L 31/00

(52) U.S. Cl. 136/293; 136/244

(57) ABSTRACT

A solar cell array control device has a plurality of solar cell modules, a bidirectional DC converter, at least a voltage sensor and a control unit. The bidirectional DC converter corresponds to and is electrically connected to the solar cell modules to connect these solar cell modules in series to form a solar cell array. The voltage sensor is electrically connected to the solar cell modules, and can generate an abnormal voltage when detecting that one of the solar cell modules is abnormal. The control unit is electrically connected to the voltage sensor and the bidirectional DC converter, and outputs a pulse width modulation signal by detecting the abnormal voltage to control the bidirectional DC converter for compensating the conversion current and thus enhancing the output power of this solar cell module.

### FIELD OF THE INVENTION

The present invention relates to a solar cell array control device and, more particularly, to a device capable of detecting whether a plurality of solar cell modules is abnormal and properly controlling each solar cell module to operate at the maximum power.

### BACKGROUND OF THE INVENTION

A solar cell is an energy storage device for converting solar energy into electric energy. In practical applications, a plurality of solar cells is usually assembled into a plurality of solar cell modules, which are connected together in series to form a solar cell array for enhancing the output power. Finally, a solar cell converter is used for the maximum power output conversion of the whole solar cell array.

When the solar cell array is used, however, the whole output power may be affected due to different environments. For instance, part of the solar cell modules in the solar cell array may be shielded to lower their output power or even have no output power to form a load mode, hence affecting the output power of the whole solar cell array.

In the prior art, a KW or above solar cell converter integrates the powers of all solar cell modules to provide the output power of the whole solar cell array. This kind of solar cell converter does not allow each solar cell module to operate at its maximum output power. Therefore, the output power provided by this kind of solar cell converter is in fact not the maximum.

Conventionally, the problem of series connection between solar cell modules is not taken into consideration in the design of a solar cell converter. In a solar cell array formed by connecting several solar cell modules in series, the solar cell modules may differ due to different environmental factors. Operation of that each solar cell module at the maximum output power cannot be ensured. If part of the solar cell modules operate in a load mode, the power of other solar cell modules will be dissipated, hence not accomplishing the expected performance when the solar cell modules are connected together in series to form the solar cell array.

Accordingly, the present invention proposes a solar cell array control device, which makes use of a detection and compensation mechanism to detect whether one of the series-connected solar cell modules is abnormal. Through properly controlling the electric power conversion of a bidirectional DC converter, each solar cell module can operate at the maximum power point.

### SUMMARY OF THE INVENTION

The primary object of the present invention is to provide a solar cell array control device, which makes use of a bidirectional DC converter to connect several solar cell modules in series and a detection and compensation mechanism to detect whether each solar cell module is abnormal. Through properly controlling the power conversion of the bidirectional DC converter, each solar cell module can operate at the maximum power.

To achieve the above object, the present invention provides a solar cell array control device, which comprises a plurality of solar cell modules, a bidirectional DC converter, at least a voltage sensor and a control unit. The bidirectional DC converter corresponds to and is electrically connected to the solar cell modules to series connect these solar cell modules in series to form a solar cell array. The voltage sensor is electrically connected to the solar cell modules, and can generate an abnormal voltage when detecting that one of the solar cell modules is abnormal. The control unit is electrically connected to the voltage sensor and the bidirectional DC converter, and outputs a pulse width modulation (PWM) signal by detecting the abnormal voltage to control the bidirectional DC converter for compensating the conversion current and thus enhancing the output power of this solar cell module.

It is preferred that the solar cell array control device of the present invention further comprise an AC/DC converter capable of tracking the maximum power. The AC/DC converter is electrically connected to the output terminals of the bidirectional DC converter to convert the output power of the solar cell array into an AC power connected in shunt with the public electric power grid or used as an independent power source.

It is preferred that the bidirectional DC converter in the solar cell array control device of the present invention further comprise a flyback transformer and a plurality of electronic switches. The flyback transformer corresponds to and is electrically connected to the output terminals of the solar cell modules to connect all the solar cell modules in series. Each electronic switch corresponds to and is connected in series to an input terminal of the flyback transformer, and has a pulse width modulation input terminal through which the pulse width modulation signal can be input to compensate the conversion current of the solar cell module for enhancing the output power.

It is also preferred that the solar cell control device of the present invention further comprise a drive circuit electrically connected between the bidirectional DC transformer and the control unit to amplify the pulse width modulation signal and drive the bidirectional DC converter to switch the pulse width for compensating the conversion current.

### BRIEF DESCRIPTION OF THE DRAWINGS

The various objects and advantages of the present invention will be more readily understood from the following detailed description when read in conjunction with the appended drawings, in which:

FIG. 1 is an architecture diagram according to an embodiment of the present invention;

FIG. 2 is a control flowchart of the present invention;

FIGS. 3A and 3B are equivalent circuit diagrams of the present invention;

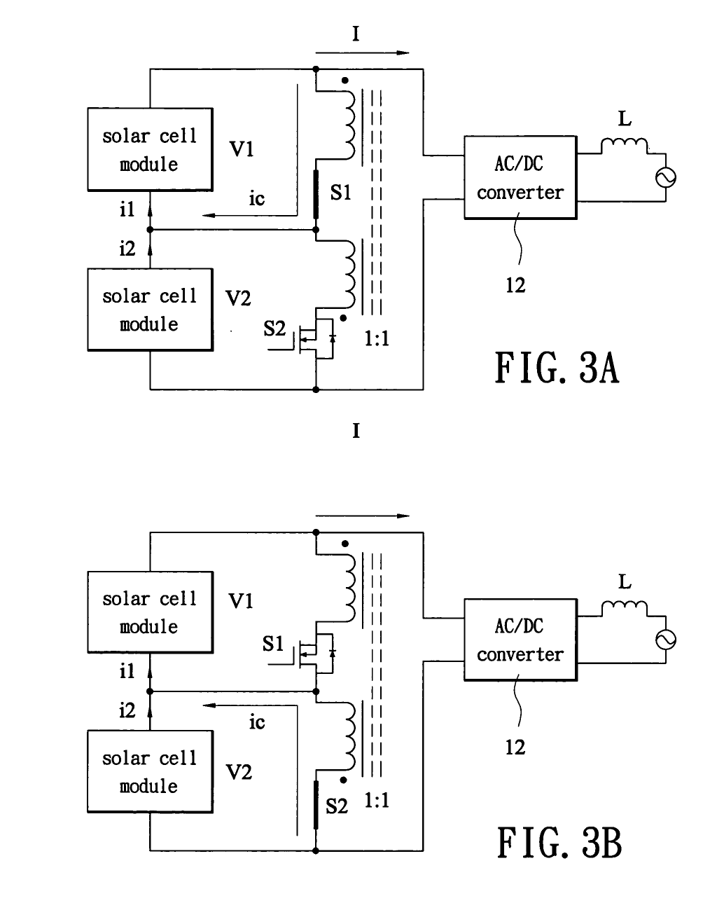

FIGS. 4A and 4B are waveform diagrams showing the pulse width modulation signal and switching of the electronic switch of the present invention; and

FIG. 5 shows the voltage-current characteristic curve of a solar cell array according to an embodiment of the present invention.

### DETAILED DESCRIPTION OF THE PREFERRED EMBODIMENTS

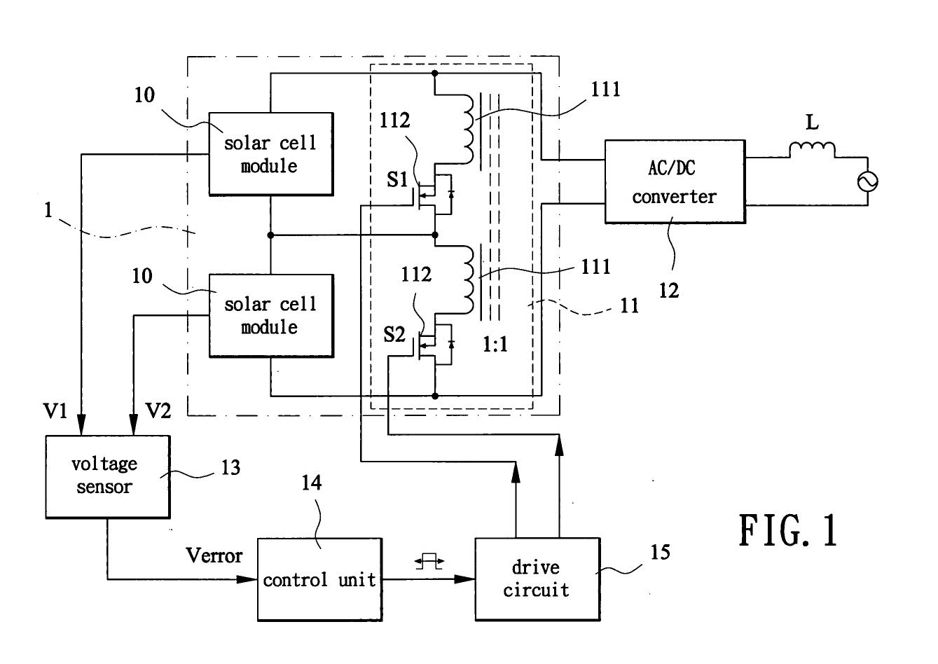

As shown in FIG. 1, the present invention applies to a solar cell array 1 formed by series connecting a plurality of solar cell modules 10 to control all the solar cell modules 11 to operate at the maximum power. Each solar cell module 11 is composed of at least a solar cell panel and at least a storage battery. The solar panel can convert solar energy into electric energy stored into the storage battery.

A bidirectional DC converter 11 is used to series connect all the solar cell modules 10 in the present invention. The bidirectional DC converter 11 is composed of a flyback transformer 111 and a plurality of electronic switches 112. The turn ratio of the flyback transformer 111 is unified. The flyback transformer 111 has a plurality of input terminals corresponding to and electrically connected to output terminals of the solar cell modules 10 for series connecting all the solar cell modules 10. The electronic switch 112 can be a high power MOSFET, and corresponds to and is connected in series to one of the input terminals of the flyback transformer 111. The electronic switch 112 has a pulse width modulation input terminal (the gate of the MOSFET) through which a pulse width modulation signal can be input to control the compensation current to enhance the output power when one of the solar cell modules is abnormal.

An AC/DC converter 12 capable of tracking the maximum power can be electrically connected to an output terminal of the bidirectional DC converter 11 to convert the output power of the solar cell array 1 into an AC power connected in shunt with the public electric power grid or used as an independent power source.

In the present invention, in order to let all the solar cell modules 11 operate at the maximum power, a detection and compensation mechanism is designed to detect the voltage value of each solar cell module and to determine whether the solar cell module is abnormal (e.g., operating in the load mode). When there is an abnormal situation, the power factor enhancement technique, i.e., the pulse width modulation technique for switching power conversion, is used to compensate the conversion current of the solar cell module 10 for accomplishing the object of enhancing the whole power factor.

In the present invention, in addition to the bidirectional DC converter 11, the detection and compensation mechanism also comprises at least a voltage sensor 13, a control unit 14 and a drive circuit 15. The voltage sensor 13 can be a comparator having a plurality of input terminals electrically connected to the solar cell modules 11. The voltage sensor 13 is used to compare the voltage values (Vpvm1, Vpvm2) of at least an arbitrary two of the solar cell modules 10 to see whether the absolute value of the voltage difference of these two solar cell modules 10 is larger than a set value (Vset). If one of the solar cell modules 10 is abnormal, an abnormal voltage (Verror) will be generated and output to the control unit 14.

The control unit 14 is electrically connected to the voltage sensor 13 and the drive circuit 15. The drive circuit 15 is electrically connected to the bidirectional DC converter 11. The control unit 14 can be a microprocessor for executing a pulse width modulation procedure. The control unit 14 can output the pulse width modulation signal for controlling the bidirectional DC converter 11 to the drive circuit 15 by determining the abnormal voltage (Verror). The drive circuit 15 will amplify the pulse width modulation signal and then inputs to the pulse width modulation input terminal (the gate of the MOSFET) of the electronic switch 112 in the bidirectional DC converter 11 to switch the power conversion pulse width for compensating the conversion current and thus enhancing the output power of this solar cell module 10.

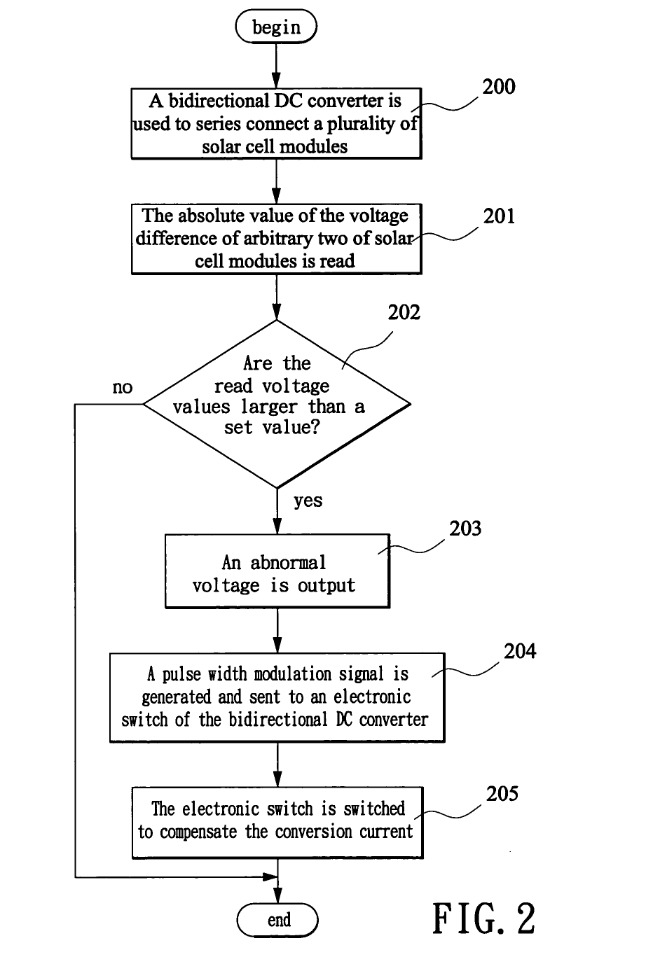

FIG. 2 is a control flowchart of the present invention. First, the bidirectional DC converter 11 is built to connect all the solar cell modules 10 in series (Step 200). The voltage values V1 and V2 of a first solar cell module 101 and a second solar cell module 102 are then read (Step 201). Next, the absolute value of the difference of the two voltages V1 and V2 (i.e., |V1-V2|) is calculated to see whether it is larger than the set value Vset (Step 202). If the answer is yes, the abnormal voltage Verror>0 is output; otherwise the abnormal voltage Verror is set to zero, meaning that the first and second solar cell modules 101 and 102 are operating at the maximum power without compensating the conversion current.

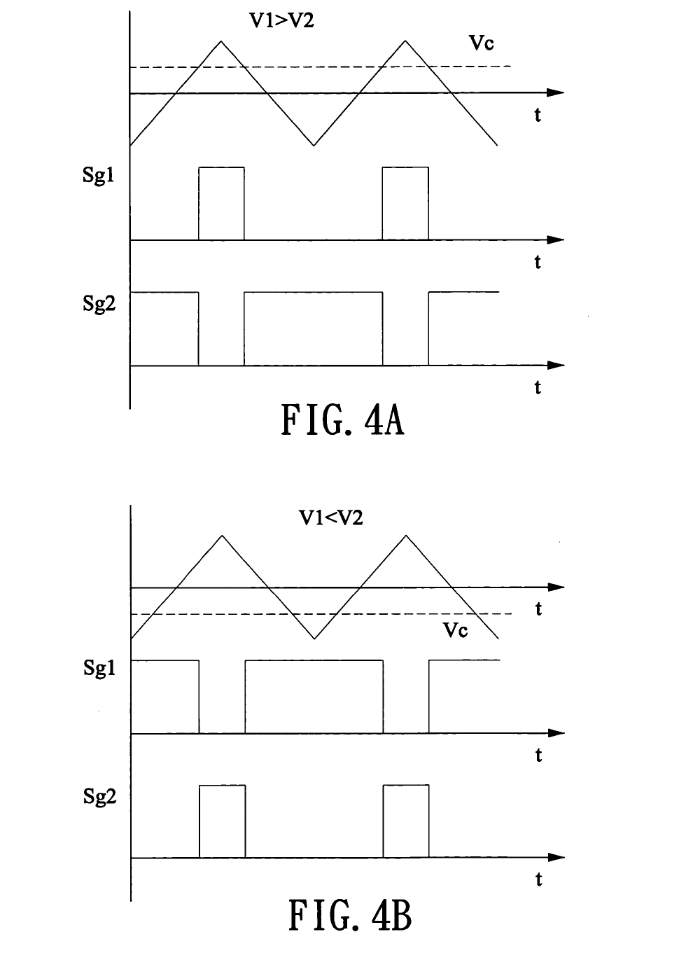

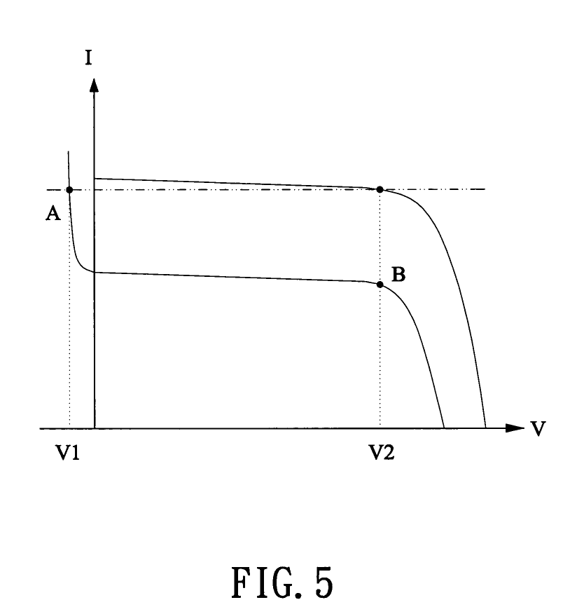

If the second solar cell module 102 is abnormal, V1 will be larger than V2 (e.g., point A shown in FIG. 5), and the abnormal voltage Verror>0 will be output to the control unit 14 (Step 203). The control unit 14 will then generate a pulse width modulation signal (shown in FIG. 4) sent to the pulse width modulation input terminals (MOSFET gates Sg1, Sg2) of electronic switches S1 and S2 (Step 204). The pulse width modulation signal is used to control the electronic switches S1 and S2 to let the current on the second solar cell module 102 (I2) be equal to the current on the first solar cell module 101 (I1) minus the total current (Ic) for compensating the conversion current of the second solar cell module 102 (e.g., the point B shown in FIG. 5) (Step 205). It is evident that the output power of the second solar cell module 102 has been enhanced.

To sum up, the present invention provides a solar cell array control device, which makes use of a bidirectional DC converter to series connect all solar cell modules and a detection and compensation mechanism to detect whether each solar cell modules is abnormal. Through properly controlling the electric power conversion of the bidirectional DC converter, each solar cell module can operate at the maximum power.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

1. A solar cell array control device, comprising:
a plurality of solar cell modules connected together in series to form a solar cell array;
a bidirectional DC converter having a plurality of input terminals corresponding to and electrically connected to output terminals of said solar cell modules for connecting all of said solar cell modules in series, said bidirectional DC converter being capable of inputting a pulse width modulation signal to control a compensation current when abnormality is detected in one of said solar cell modules;
at least a voltage sensor having a plurality of input terminals electrically connected to said solar cell modules, said voltage sensor being capable of generating an abnormal voltage when abnormality is detected in one of said solar cell modules; and
a control unit electrically connected to said voltage sensor and said bidirectional DC converter, said control unit being used to output said pulse width modulation signal by determining said abnormal voltage to control said bidirectional DC converter for compensating the conversion current and thus enhancing an output power of said solar cell modules.

2. The solar cell array control device as claimed in claim 1, wherein each said solar cell module is composed of at least a solar panel and at least a storage battery, and said solar panel is used to convert solar energy into electric energy stored into said storage battery.

3. The solar cell array control device as claimed in claim 1, further comprising an AC/DC converter capable of tracking the maximum power, said AC/DC converter being electrically connected to an output terminal of said bidirectional DC converter and used to convert the output power of said solar cell array into an AC power connected in shunt with the public electric power grid or used as an independent power source.

4. The solar cell array control device as claimed in claim 1, wherein said bidirectional DC converter further comprises:
a flyback transformer having a plurality of series-connected input terminals corresponding to and electrically connected to the output terminals of said solar cell modules for connecting all of said solar cell modules in series; and
a plurality of electric switches corresponding to and series connected to the input terminals of said flyback transformer, each said electric switch having a pulse width modulation input terminal, and said pulse width modulation signal being input through said pulse width modulation input terminal to compensate the conversion current of one of said solar cell modules for enhancing the output power.

5. The solar cell array control device as claimed in claim 4, wherein said electric switch is a high power MOSFET.

6. The solar cell array control device as claimed in claim 1, wherein said voltage sensor is a comparator used to compare voltage values of at least arbitrary two of said solar cell modules electrically connected to said input terminals of said voltage sensor and output an abnormal voltage to said control unit when an absolute value of the voltage difference of said two solar cell modules is larger than a set value.

7. The solar cell array control device as claimed in claim 1, wherein said control unit is a microprocessor used to execute an abnormal pulse width modulation procedure and output said pulse width modulation signal when one of said solar cell modules is abnormal, thereby controlling said bidirectional DC converter to compensate the conversion current and thus enhance the output power of said solar cell module.

8. The solar cell array control device as claimed in claim 1 further comprising a drive circuit electrically connected between said bidirectional DC converter and said control unit and used to amplify said pulse width modulation signal and drive said bidirectional DC converter to switch the pulse width for compensating the conversion current.

9. A solar cell array control method comprising the steps of:
a. building a bidirectional DC converter to connect a plurality of solar array modules in series to form a solar cell array;
b. reading a voltage value of at least an arbitrary two of said solar cell modules;
c. calculating a read voltage value to determine whether said read voltage values is larger than a set value and output an abnormal voltage if an answer is yes; and
d. generating a pulse width modulation signal input to said bidirectional DC converter to switch the pulse width for compensating the conversion current of said solar cell modules and thus enhancing the output power.

10. The solar cell array control method as claimed in claim 9, wherein at least a voltage sensor is used to read the voltage value of said solar cell modules in said step b.

11. The solar cell array control method as claimed in claim 9, wherein an absolute value of the voltage difference of the arbitrary two of said solar cell modules is calculated to determine whether the absolute value of the voltage difference is larger than said set value and output said abnormal voltage if an answer is yes in said step c.

12. The solar cell array control method as claimed in claim 9, wherein said abnormal voltage is set to zero if said voltage value is not larger than said set value in said step c.

13. The solar cell array control method as claimed in claim 9, wherein said pulse width modulation signal is used to control an electronic switch to switch an output pulse width of said solar cell modules for compensating the conversion current in said step d.
